(19) United States
(12) Patent Application Publication
(10) Pub. No.: US 2014/0368278 A1
(43) Pub. Date: Dec. 18, 2014

(54) Using Multiple-Driver Stages to Realize Fast Rise/Fall Time And Large Current Capability

(71) Applicant: AURIGA MEASUREMENT SYSTEMS, LLC, Chelmsford, MA (US)

(72) Inventor: Yusuke Tajima, Acton, MA (US)

(73) Assignee: AURIGA MEASUREMENT SYSTEMS, LLC, Chelmsford, MA (US)

(21) Appl. No.: 14/307,971

(22) Filed: Jun. 18, 2014

Related U.S. Application Data
(60) Provisional application No. 61/836,242, filed on Jun. 18, 2013.

(51) Int. Cl. H03F 3/193; H03F 3/24

(52) U.S. Cl. CPC H03F 3/193; H03F 3/245; H03F 2200/451
USPC 330/296

(57) ABSTRACT

A driver circuit includes a first sub-driver circuit having an input coupled to receive a first pulsed signal, the first sub-driver circuit being configured to generate a first driver signal at an output thereof in response to the first pulsed signal, the first driver signal having relatively fast edge transitions and a low current capability. Also included is a second sub-driver circuit having an input coupled to receive a second pulsed signal, the second sub-driver circuit being configured to generate a second driver signal at an output thereof in response to the second pulsed signal, the second driver signal having edge transitions that are slower than those of the first driver signal and a current capability that is higher than that of the first driver signal. Further included is a combiner to combine the first driver signal and the second driver signal to generate a combined driver signal having fast edge transitions associated with the first driver signal and higher current capability associated with the second driver signal. A corresponding method is also provided.

### CROSS REFERENCE TO RELATED APPLICATIONS

The present application claims the benefit of U.S. Provisional Application No. 61/836,242, filed on Jun. 18, 2013, which is hereby incorporated by reference herein in its entirety.

### STATEMENT REGARDING FEDERALLY SPONSORED RESEARCH

Not Applicable.

### FIELD

This disclosure relates generally to radio frequency (RF) circuits and, more particularly, to techniques and circuits for operation of multiple driver stages with RF amplifier circuits.

### BACKGROUND

The subject matter described herein relates generally to radio frequency (RF) circuits and, more particularly, to techniques and circuits for operating RF amplifier circuits, utilizing RF signals directly generated by pulse modulation. The pulse width of RF signals is modulated to achieve amplitude modulation and pulse position is modulated to achieve phase modulation with digitally-modulated waveforms used in conventional modern communication systems. Modulated pulses provide for software-reconfigurability to accommodate different communication standards, typically make a transmitter immune to RF impairments such as I-Q imbalance, carrier leakage, etc and remove the need for components to perform frequency conversion.

To meet desired power requirements, pulsed systems generally include an RF power amplifier (PA) circuit and a driver circuit comprising one or more driver stages (or sub-driver circuits). The driver stages are typically inserted into an RF signal path prior to the RF PA circuit for the purpose of receiving pulsed signals from one or more pulsed signal generator circuits and driving the RF PA circuit.

In some applications, it is critical for the driver stages to maintain the pulse shape-such that the driver stages drive the RF PA circuit with signals having a desired output power and rise/fall times that are substantially the same as the original rise/fall times associated with the pulsed signal received by the driver stages. By maintaining the rise/fall times, the RF PA stage is capable of outputting signals (e.g., RF output signals) having the same signal integrity as the input signal.

It is, however, difficult to provide a driver circuit capable of driving a RF PA stage with a desired current level while maintaining rise/fall times associated with received pulsed signals.

It would therefore be desirable to provide a driver circuit capable of driving a RF PA stage with a desired current level while maintaining rise/fall times associated with a received pulsed signal. This would require a driver circuit to be capable of efficiently providing driver signals having both a high power capability and fast rise/fall time capability simultaneously.

### SUMMARY

Described herein is a driver circuit capable of driving a RF PA stage with a desired current level while maintaining rise/fall times associated with a received pulsed signal. Techniques described herein provide a driver circuit capable of efficiently providing driver signals having both a high power capability and fast rise/fall time capability simultaneously.

In one aspect, a driver circuit includes a first sub-driver circuit having an input coupled to receive a first pulsed signal, the first sub-driver circuit being configured to generate a first driver signal at an output thereof in response to the first pulsed signal, the first driver signal having relatively fast edge transitions and a low current capability. The driver circuit additionally includes a second sub-driver circuit having an input coupled to receive a second pulsed signal, the second sub-driver circuit being configured to generate a second driver signal at an output thereof in response to the second pulsed signal, the second driver signal having edge transisions that are slower than those of the first driver signal and a current capability that is higher than that of the first driver signal. The driver circuit further includes a combiner to combine the first driver signal and the second driver signal to generate a combined driver signal having fast edge transitions associated with the first driver signal and higher current capability associated with the second driver signal. Duration of the fast edge transisions is short and the total amount of current that the first driver has to support is much smaller than the total current from the second driver which has to support the current during the duration of the each pulse, although the speed of the pulse could be much slower.

Features of the driver circuit may include one or more of the following either individually or in combination. The first pulsed signal is provided from a first pulsed signal generator circuit and the second pulsed signal is provided from a second pulsed signal generator circuit. The first pulsed signal and the second pulsed signal are provided from a single pulsed signal generator circuit. The driver circuit further includes a splitter circuit having an input coupled to receive a pulsed input signal from the single pulsed signal generator circuit, said splitter circuit being configured to generate a first split signal at a first splitter circuit output and a second split signal at a second splitter circuit output in response to the pulsed input signal, such that the first split signal is provided as the first pulsed signal and the second split signal is provided as the second pulsed signal.

Features of the driver circuit may additionally include one or more of the following either individually or in combination. The first pulsed signal includes both positive and negative pulse values. The driver circuit additionally includes a third sub-driver circuit having an input coupled to receive a third pulsed signal, the third sub-driver circuit being configured to generate a third driver signal at an output thereof in response to the third pulsed signal, the third driver signal having edge transitions that are substantially the same as the first driver signal but having negative pulse values, wherein the combiner is capable of combining the first driver signal and the second driver signal with the third driver signal to generate a combined driver signal having fast edge transitions associated with the first and third driver signals and higher current capability associated with the second driver signal.

In another aspect, an amplifier circuit includes a driver circuit and a power amplifier (PA) circuit. The driver circuit includes a first sub-driver circuit having an input coupled to receive a first pulsed signal, the first sub-driver circuit being configured to generate a first driver signal at an output thereof in response to the first pulsed signal, the first driver signal having relatively fast edge transitions and a low current capability. The driver circuit additionally includes a second sub-driver circuit having an input coupled to receive a second pulsed signal, the second sub-driver circuit being configured to generate a second driver signal at an output thereof in response to the second pulsed signal, the second driver signal having edge transisions that are slower than those of the first driver signal and a current capability that is higher than that of the first driver signal. The driver circuit also includes a combiner to combine the first driver signal and the second driver signal to generate a combined driver signal having fast edge transitions associated with the first driver signal and higher current capability associated with the second driver signal.

The PA circuit is coupled to receive the combined driver signal at an input thereof. Additionally, the PA is configured to amplify the combined driver signal to generate an amplified output signal at an output thereof, wherein the edge transitions and current capability of the combined driver signal are sufficient to provide desired operating characteristics for the amplifier circuit.

Features of the amplifier circuit may include one or more of the following either individually or in combination. The first pulsed signal is provided from a first pulsed signal generator circuit and the second pulsed signal is provided from a second pulsed signal generator circuit. The first pulsed signal and the second pulsed signal are provided from a single pulsed signal generator circuit. The driver circuit further includes a splitter circuit having an input coupled to receive a pulsed input signal from the single pulsed signal generator circuit, said splitter circuit being configured to generate a first split signal at a first splitter circuit output and a second split signal at a second splitter circuit output in response to the pulsed input signal, such that the first split signal is provided as the first pulsed signal and the second split signal is provided as the second pulsed signal.

In another aspect, a method of driving an amplifier circuit includes generating a first driver signal and a second driver signal, the first driver signal having faster edge transitions than the second driver signal and the second driver signal having greater current capability than the first driver signal. The method additionally includes combining the first and second driver signals to generate a combined driver signal having a high power capability and a fast rise/fall time capability. The method also includes providing the combined driver signal to an input of the amplifier circuit for generating an amplified output signal from the combined driver signal.

Features of the method may include one or more of the following either individually or in combination. Generating a first driver signal includes generating the first driver signal with a first sub-driver circuit in response to a first pulsed signal received from a first pulsed signal generator and generating a second driver signal includes generating the second driver signal with a second sub-driver circuit in response to a second pulsed signal received from a second pulsed signal generator. Generating a first driver signal includes generating the first driver signal with a first sub-driver circuit in response to a first pulsed signal received from a first output of a spatter circuit and generating a second driver signal Includes generating the second driver signal with a second sub-driver circuit in response to a second pulsed signal received from a second output of the spatter circuit.

### BRIEF DESCRIPTION OF THE DRAWINGS

The foregoing features of the disclosure, as well as the disclosure itself may be more carefully understood from the following detailed description of the drawings, in which:

FIG. 1 is a block diagram of an example radio frequency (RF) amplifier circuit including a driver circuit coupled to an RF power amplifier circuit;

FIG. 1A is a block diagram of another example radio frequency (RF) amplifier circuit including a driver circuit coupled to an RF power amplifier circuit;

FIG. 1B is a block diagram of another example radio frequency (RF) amplifier circuit including a driver circuit coupled to an RF power amplifier circuit;

FIG. 2 is a block diagram of another example embodiment of a RF amplifier circuit including a driver circuit coupled to an RF power amplifier circuit; and

FIG. 3 is a plot of current versus time for an example combined signal produced by combining outputs of a driver circuit which may be the same as or similar to the driver circuits of FIGS. 1 and 2.

### DETAILED DESCRIPTION

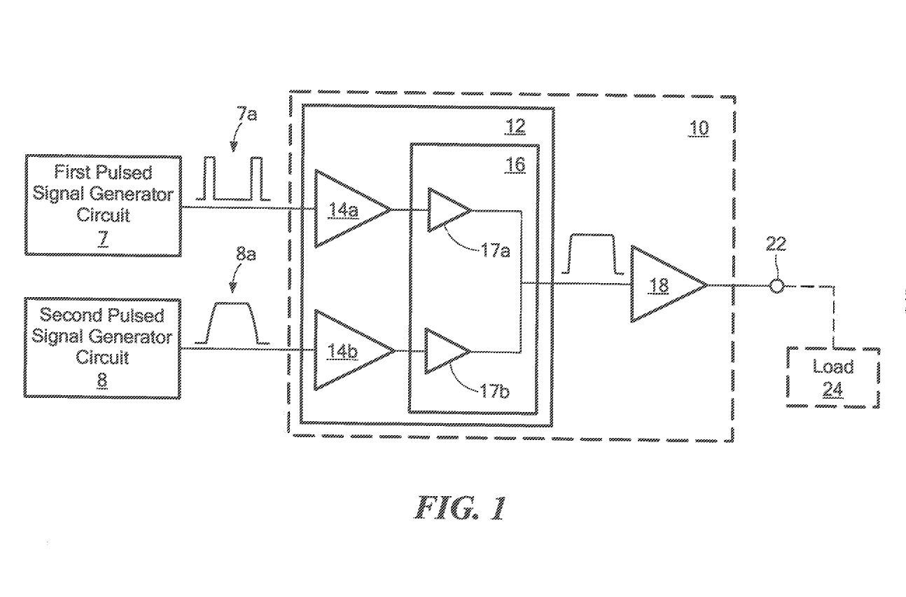

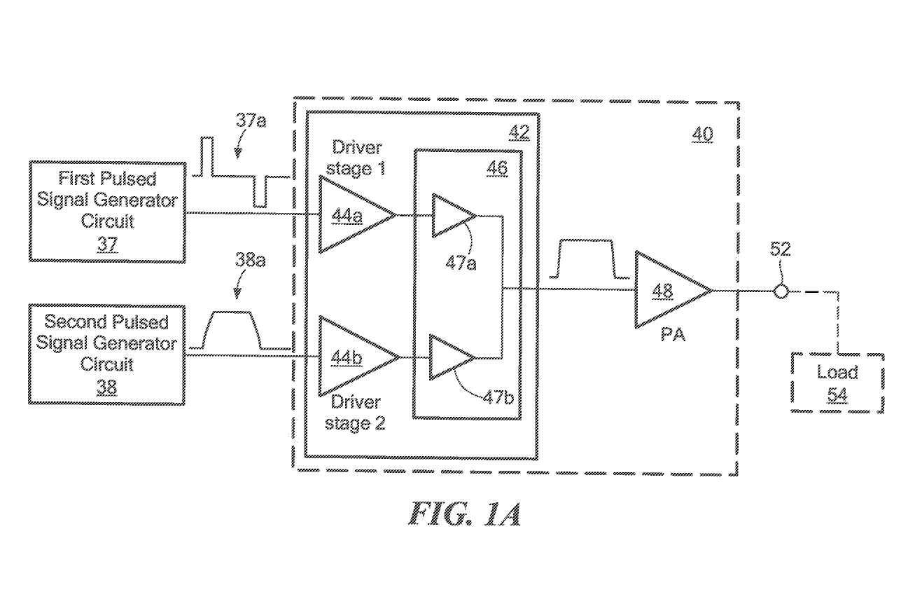

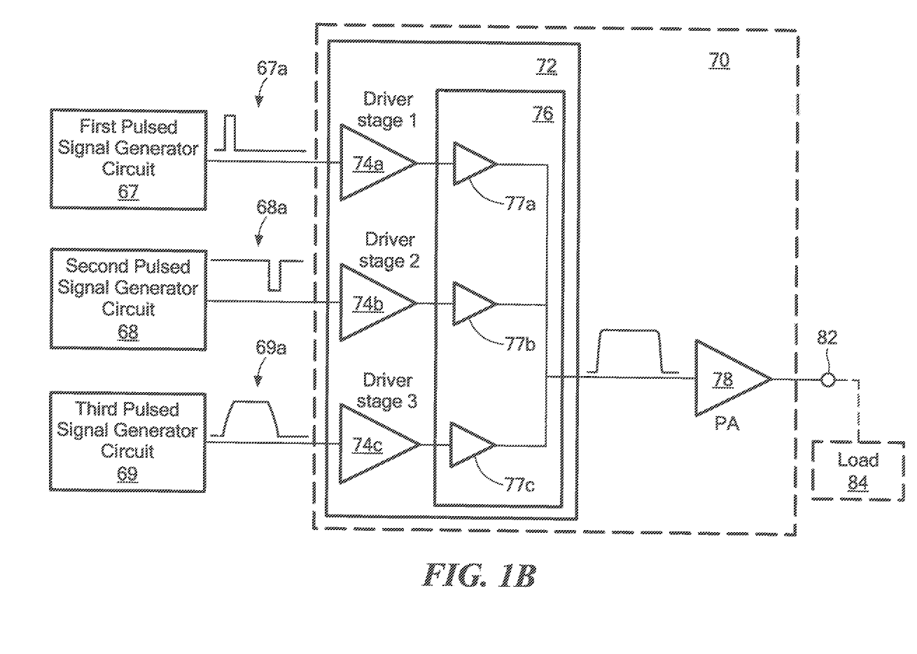

The features and other details of the concepts, systems, circuits and techniques sought to be protected herein will now be more particularly described. It will be understood that any specific embodiments described herein are shown by way of illustration and not as limitations of the disclosure. The principal features of this disclosure can be employed in various embodiment without departing from the scope of the concepts sought to be protected. The preferred embodiments of the present disclosure and associated advantages are best understood by referring to FIGS. 1-3 of the drawings, like numerals being used for like and corresponding parts of the various drawings.

### Definitions

For convenience, certain introductory concepts and terms used in the specification are collected here.

As used herein, the term “rise time” is used to describe the time taken by a signal to increase (rise) from a specified low value to a specified high value. Typically, these values are about 10% and about 90% of the step height associated with the signal, respectively. In general, however, rise time may be defined as the time required for a signal to rise from 10% to 90% of its final value. Thus, a “fast” rise time is a rise time which is a short period of time (i.e., the phrases “fast rise time” and “short rise time” are equivalent).

As used herein, the term “fall time” is used to describe the time taken by a signal to decrease (fall) from a specified high value to a specified low value. Typically, these values are about 90% of a peak value exclusive of overshoot or undershoot to another specified value—about 10% of the maximum value exclusive of overshoot or undershoot. Thus, a “fast” fall time is a fall time which is a short period of time (i.e., the phrases “fast fall time” and “short fall time” are equivalent).

As used herein, the term “processor” is used to describe an electronic circuit that performs a function, an operation, or a sequence of operations. The function, operation, or sequence of operations can be hard coded into the electronic circuit or soft coded by way of instructions held in a memory device. A “processor” can perform the function, operation, or sequence of operations using digital values or using analog signals.

In some embodiments, the “processor” can be embodied, for example, in a specially programmed microprocessor, a digital signal processor (DSP), or an application specific integrated circuit (ASIC), which can be an analog ASIC or a digital ASIC. Additionally, in some embodiments the “processor” can be embodied in configurable hardware such as field programmable gate arrays (FPGAs) or programmable logic arrays (PLAs). In some embodiments, the “processor” can also be embodied in a microprocessor with associated program memory. Furthermore, in some embodiments the “processor” can be embodied in a discrete electronic circuit, which can be an analog or digital.

Referring now to FIG. 1, a radio frequency (RF) amplifier circuit 10 includes a driver circuit 12 coupled to an input of an RF power amplifier 18 which may, for example, be provided as a power amplifier (PA) comprising one or more amplifying devices. In this example embodiment, the driver circuit 12 and the RF power amplifier 18 are shown as a part of the RF amplifier circuit 10. It should, of course, be appreciated that in other embodiments the driver circuit 12 and the RF power amplifier 18 may not be a part of the RF amplifier circuit 10 and thus RF amplifier circuit 10 is shown in phantom lines in FIG. 1.

The RF amplifier circuit 10 has first and second inputs adapted to couple to a plurality of pulsed signal generator circuits (first pulsed signal generator circuit 7, second pulsed signal generator circuit 8). In one embodiment, the first pulsed signal generator circuit 7 generates pulses having differing characteristics (e.g., pulse width, rise/fall times) than pulses generated by the second pulsed signal generator circuit 8. For example, in the illustrated embodiment, the first pulsed signal generator circuit 7 generates short pulses having fast rise/fall times (or more simply, a “first pulsed signal” 7a) and the second pulsed signal generator circuit 8 generates longer pulses having slower rise/fall times (or more simply, a “second pulsed signal” 8a). The first and second pulsed signal generator circuits 7, 8 can, for example, be controlled by a processor (not shown) coupled to or included within the RF amplifier circuit 10, but it is not so limited. In one embodiment, the first and second pulsed signal generator circuits 7, 8 are synchronized such that the first pulsed signal 7a and the second pulsed signal 8a are output at substantially the same time and capable of being later combined in accordance with the synchronization.

The driver circuit 12, which includes first and second “sub-driver circuits” 14a, 14b and a combiner circuit 16 in the example embodiment shown, has first and second inputs coupled to the first and second inputs of RF amplifier circuit 10. The first sub-driver circuit 14a has an input coupled to the first driver circuit input and the second sub-driver circuit 14b has an input coupled to the second driver circuit input. The first sub-driver circuit 14a receives the first pulsed signal 7a and in response thereto generates a first driver signal at an output thereof. In one embodiment, the first driver signal is a representative signal of the first pulsed signal 7a having a low current capacity.

The second sub-driver circuit 14b receives the second pulsed signal 8a and in response thereto generates a second driver signal at an output thereof. In one embodiment, the second driver signal is a representative signal of the second pulsed signal 8a having a higher current capacity than that of the first driver signal. In this embodiment, the current capacity of the second sub-driver circuit 14b is 10 times larger than the first circuit. In such embodiments, the first and second sub-driver circuits 14a, 14b may be provided having comparable frequency responses. However, in one embodiment, the rise and fall times associated with the first and second sub-driver circuits 14a, 14b are different. In the example embodiment shown, energy storage capacitors used in the first and second sub-driver circuits 14a, 14b have a ratio of 1:10. As a result, the current capacity ratio of the first and second sub-driver circuits 14a, 14b are 1:10 while the edge transitions times (i.e., rise/fall times) associated with the first sub-driver circuit 14a is substantially shorter than edge transitions times associated with the second sub-driver circuit 14b. It is to be appreciated that although driver circuit 12 is shown comprising two sub-driver circuits (i.e., first sub-driver circuit 14a and second sub-driver circuit 14b), in some embodiments driver circuit 12 may comprise more than two driver circuits, as will be apparent in the discussions of FIG. 1B.

The combiner circuit 16, which is provided from a pair of diodes 17a, 17b in the example embodiment shown, has a first input coupled to the first sub-driver circuit output and a second input coupled to the second sub-driver circuit output. Combiner circuit 16 receives the first and second driver signals and in response thereto combines the first and second driver signals to generate a combined (or composite) driver signal at an output thereof. In one embodiment, the combiner circuit 16 can be provided as a passive 3 dB combiner. However, it is to be appreciated that such 3 dB combiner may produce losses, and having losses on the output side of the driver circuit 12 is undesirable and inefficient. Accordingly, having a more efficient combiner circuit 16 is desirable. In one embodiment, the combined driver signal includes a fast rise/fall time (e.g., from the first driver signal produced by the first sub-driver circuit 14a) and a high power level (e.g., from the second driver signal produced by the second sub-diver circuit 14b). In the example embodiment shown, the driver circuit 12 has an output coupled to the combiner circuit output.

The RF PA 18 has an input coupled to the driver circuit output. RF PA 18 receives the combined driver signal and in response thereto generates an RF output signal at an output thereof. In one embodiment, the RF PA output forms an output 22 of the RF amplifier circuit 10. The RF output signal of the RF amplifier circuit 10 can, for example, be delivered to a load 24 (e.g., an antenna).

In an embodiment where the load 24 is an antenna, the load 24 will receive the RF output signal of the RF amplifier circuit 10 and, in response thereto, transmit the RF output signal into free space. In other embodiments, other types of loads 24 may be used (e.g., other types of transducers, signal processing circuitry to provide further processing, etc.). It is to be appreciated that RF amplifier circuit 10 may be found suitable in other environments besides RF transmit systems.

In operation, a characteristic of driver circuit 12 is that at least one of the plurality of driver circuits (here, first sub-driver circuit 14a) is capable of generating driver signals having fast rise/fall times but is not necessarily capable of generating an amount of current necessary to provide the RF PA 18 with a desired output power level (i.e., the driver output signal has a relatively low current). Another characteristic of driver circuit 12 is that at least one of the plurality of sub-driver circuits (here, second sub-driver circuit 14b) is capable of generating an amount of current necessary to provide the RF PA 18 with a desired output power level but is not necessarily capable of supporting rise/fall time characteristics required by the RF PA 18. Overall, however, the driver circuit 12 is capable of generating pulses and driving the RF PA circuit 18 with fast rise/fall times at a desired current level such that RF PA circuit 18 is capable of providing pulsed signals at desired power levels while at the same time having pulses with desired rise/fall times.

Referring now to FIG. 1A, in which like elements of FIG. 1 are shown having similar reference designations, an example radio frequency (RF) amplifier circuit 40 includes a driver circuit 42 coupled to an input of an RF power amplifier 48 which may, for example, be provided as a power amplifier (PA) comprising one or more amplifying devices. In this example embodiment, the driver circuit 42 and the RF power amplifier 48 are shown as a part of the RF amplifier circuit 40. It should, of course, be appreciated that in other embodiments the driver circuit 42 and the RF power amplifier 48 may not be a part of the RF amplifier circuit 40 and thus RF amplifier circuit 40 is shown in phantom lines in FIG. 1A. The driver circuit 42 includes first and second “sub-driver circuits” 44a, 44b and a combiner circuit 46 (comprising diodes 47a and 47b) in the example embodiment shown. Additionally, the RF PA 48 has an output coupled to an output 52 which in one embodiment forms an output 52 of the RF amplifier circuit 40. Furthermore, an RF output signal generated by the RF amplifier circuit 40 can, for example, be delivered to a load 54 (e.g., an antenna).

As in FIG. 1, the RF amplifier circuit 40 has first and second inputs adapted to couple to a plurality of pulsed signal generator circuits (first pulsed signal generator circuit 37, second pulsed signal generator circuit 38). Additionally, as in FIG. 1, in one embodiment the first pulsed signal generator circuit 37 generates pulses having differing characteristics (e.g., pulse width, rise/fall times) than pulses generated by the second pulsed signal generator circuit 38. Like FIG. 1, in the illustrated embodiment the second pulsed signal generator circuit 38 generates longer pulses having slower rise/fall times (or more simply, a “second pulsed signal” 38a). In one embodiment, the second pulsed signal has only positive pulse values. However, unlike FIG. 1, in the illustrated embodiment the first pulsed signal generator circuit 37 generates short pulses having fast rise/fall times (or more simply, a “first pulsed signal” 37a) in addition to both positive and negative pulse values (first pulsed signal 7a of FIG. 1 is shown having positive pulse values). In one embodiment, the positive and negative pulse values are substantially the same. In another embodiment, they may be different.

While the first pulsed signal 37a of the example RF amplifier circuit 40 of FIG. 1A is described as being different from the first pulsed signal 7a of the example RF amplifier circuit 10 of FIG. 1, in one embodiment the operation of the RF amplifier circuit 40 is substantially the same as RF amplifier circuit 10. In particular, in operation, a characteristic of driver circuit 42 is that at least one of the plurality of driver circuits (here, first sub-driver circuit 44a) is capable of generating driver signals having fast rise/fall times but is not necessarily capable of generating an amount of current necessary to provide the RF PA 48 with a desired output power level (i.e., the driver output signal has a relatively low current). Another characteristic of driver circuit 42 is that at least one of the plurality of sub-driver circuits (here, second sub-driver circuit 44b) is capable of generating an amount of current necessary to provide the RF PA 48 with a desired output power level but is not necessarily capable of supporting rise/fall time characteristics required by the RF PA 48. Overall, however, the driver circuit 42 is capable of generating pulses and driving the RF PA circuit 48 with fast rise/fall times at a desired current level such that RF PA circuit 48 is capable of providing pulsed signals at desired power levels while at the same time having pulses with desired rise/fall times.

Referring now to FIG. 1B, in which like elements of FIGS. 1 and 1A are shown having similar reference designations, an example radio frequency (RF) amplifier circuit 70 includes a driver circuit 72 coupled to an input of an RF power amplifier 78 which may, for example, be provided as a power amplifier (PA) comprising one or more amplifying devices. In this example embodiment, the driver circuit 72 and the RF power amplifier 78 are shown as a part of the RF amplifier circuit 70. It should, of course, be appreciated that in other embodiments the driver circuit 72 and the RF power amplifier 78 may not be a part of the RF amplifier circuit 70 and thus RF amplifier circuit 70 is shown in phantom lines in FIG. 1B. Unlike FIGS. 1 and 1A, the driver circuit 72 in the example embodiment shown includes first, second and third “sub-driver circuits” 74a, 74b, 74c (rather than just first and second sub-driver circuits shown FIGS. 1 and 1A). A combiner circuit 76 (comprising diodes 77a and 77b) is coupled to receive the outputs of first, second “sub-driver circuits” 74a, 74b, 74c.

The RF amplifier circuit 70 has first, second and third inputs adapted to couple to a plurality of pulsed signal generator circuits (first pulsed signal generator circuit 67, second pulsed signal generator circuit 68, and third pulsed signal generator circuit 69). In one embodiment, the first pulsed signal generator circuit 67 generates pulses having differing characteristics (e.g., pulse width, rise/fall times) than pulses generated by both the second and third pulsed signal generator circuits 68, 69. For example, in the illustrated embodiment the first pulsed signal generator circuit 67 generates short pulses having fast rise/fall times and positive pulse values (or more simply, a “first pulsed signal” 67a). Additionally, in the illustrated embodiment the second pulsed signal generator circuit 68 generates short pulses having fast rise/fall times and negative pulse values (or more simply, a “second pulsed signal” 68a). In one embodiment, the positive pulse values of the first pulsed signal 67a are substantially the same in magnitude as the negative pulse values of the second pulsed signal 68a. In another embodiment, they may be different. Additionally, in one embodiment the positive pulse values of the first pulsed signal 67a are substantially the same as the positive pulse values of the first pulsed signal 37a of FIG. 1A and the negative pulse values of the second pulsed signal 68a are substantially the same as the negative pulse values of the first pulsed signal 37a of FIG. 1A.

In the illustrated embodiment the third pulsed signal generator circuit 69 generates longer pulses having slower rise/fall times (or more simply, a “third pulsed signal” 69a). In one embodiment, the third pulsed signal has only positive pulse values. Additionally, in one embodiment the third pulsed signal 69a is substantially the same as the second pulsed signal 8a of FIG. 1 and the second pulsed signal 38a of FIG. 1A.

The driver circuit 72 has first, second and third inputs coupled to the first, second and third inputs of RF amplifier circuit 70. The first sub-driver circuit 74a has an input coupled to the first driver circuit input, the second sub-driver circuit 74b has an input coupled to the second driver circuit input, and the third sub-driver circuit 74c has an input coupled to the third driver circuit input. The first sub-driver circuit 74a receives the first pulsed signal 67a and in response thereto generates a first driver signal at an output thereof. In one embodiment, the first driver signal is a representative signal of the first pulsed signal 67a having a low current capacity.

The second sub-driver circuit 74b receives the second pulsed signal 68a and in response thereto generates a second driver signal at an output thereof. In one embodiment, the second driver signal is a representative signal of the second pulsed signal 68a having a same current capacity than that of the first driver signal, but having a negative pulse value. The third sub-driver circuit 74c receives the third pulsed signal 69a and in response thereto generates a third driver signal at an output thereof. In one embodiment, the third driver signal is a representative signal of the third pulsed signal 69a having a higher current capacity than that of the first driver signal and the second driver signal.

In this embodiment, the current capacity of the third sub-driver circuit 74c is 10 times larger than either the first or the second sub-driver circuit 74a, 74b. In such embodiments, the first, second, and third sub-driver circuits 74a, 74b, and 74c may be provided having comparable frequency responses. However, in one embodiment, the rise and fall times associated with the first, second, and third sub-driver circuits 74a, 74b, and 74c are different. In the example embodiment shown, energy storage capacitors used in the first, second, and third sub-driver circuits 74a, 74b, and 74c have a ratio of 1:10. As a result, the current capacity ratio of the first, second, and third sub-driver circuits 74a, 74b, and 74c are 1:10 (i.e., ratio of first sub-driver circuit 74a to second sub-driver circuit 74b is 1:10, ratio of second sub-driver circuit 74b to third sub-driver circuit 74c is 1:10) while the edge transitions times (i.e., rise/fall times) associated with the first and second sub-driver circuits 74a, 74b are substantially shorter than edge transitions times associated with the third sub-driver circuit 74c.

The combiner circuit 76, which is provided from a pair of diodes 77a, 77b, 77c in the example embodiment shown, has a first input coupled to the first sub-driver circuit output, a second input coupled to the second sub-driver circuit output, and a third input coupled to the second sub-driver circuit output. Combiner circuit 76 receives the first, second, and third driver signals and in response thereto combines the first, second, and third driver signals to generate a combined (or composite) driver signal at an output thereof. In one embodiment, the combined driver signal includes a fast rise/fall time (e.g., from the first and second driver signals produced by the first and second sub-driver circuits 74a, 74b) and a high power level (e.g., from the third driver signal produced by the third sub-driver circuit 74c). In the example embodiment shown, the driver circuit 72 has an output coupled to the combiner circuit output.

The RF PA 78 has an input coupled to the driver circuit output. RF PA 78 receives the combined driver signal and in response thereto generates an RF output signal at an output thereof. In one embodiment, the RF PA output forms an output 82 of the RF amplifier circuit 70. The RF output signal of the RF amplifier circuit 70 can, for example, be delivered to a load 84 (e.g., an antenna).

While the example RF amplifier circuit 70 of FIG. 1B is described as comprising three pulsed signal generator circuits, three sub-driver circuits, and a combiner circuit for combining three driver signals and the example RF amplifier circuit 40 of FIG. 1A is described as comprising two pulsed signal generator circuits, two sub-driver circuits, and a combiner circuit for combining two driver signals, in one embodiment the operation of the RF amplifier circuit 70 is substantially the same as RF amplifier circuit 40. In particular, in operation, a characteristic of driver circuit 72 is that at least one of the plurality of driver circuits (here, first and second sub-driver circuits 74a, 74b) is capable of generating driver signals having fast rise/fall times but is not necessarily capable of generating an amount of current necessary to provide the RF PA 78 with a desired output power level (i.e., the driver output signal has a relatively low current). Another characteristic of driver circuit 72 is that at least one of the plurality of sub-driver circuits (here, third sub-driver circuit 74c) is capable of generating an amount of current necessary to provide the RF PA 78 with a desired output power level but is not necessarily capable of supporting rise/fall time characteristics required by the RF PA 78. Overall, however, the driver circuit 72 is capable of generating pulses and driving the RF PA circuit 78 with fast rise/fall times at a desired current level such that RF PA circuit 78 is capable of providing pulsed signals at desired power levels while at the same time having pulses with desired rise/fail times. It is to be appreciated that in some embodiments an RF amplifier circuit may comprise more than 3 sub-driver circuits, as apparent.

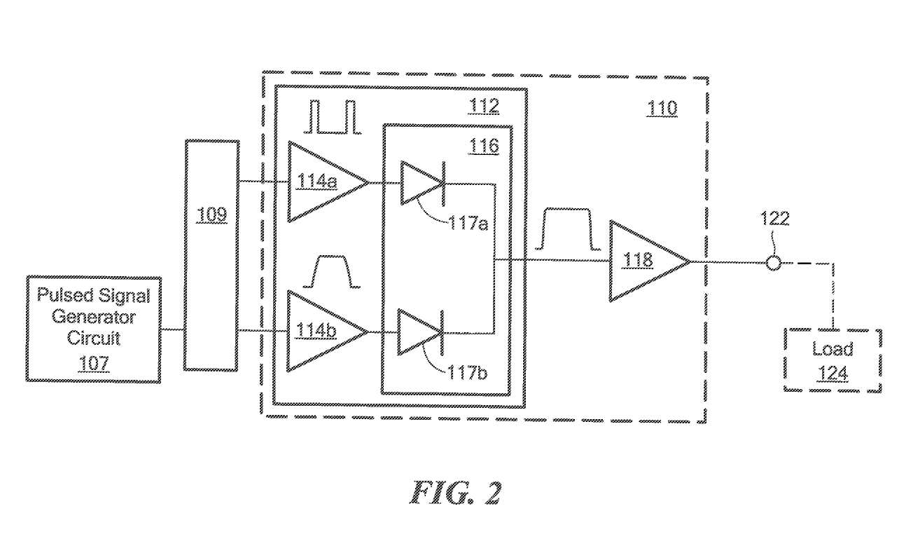

Referring now to FIG. 2, an RF amplifier circuit 110 in accordance with another example embodiment includes a driver circuit 112 and an RF PA 118 coupled as shown. In this embodiment, like the embodiment of FIG. 1, the driver circuit 112 and RF PA 118 may be provided as part of the RF amplifier circuit 110, but it is not so limited. RF amplifier circuit 110 also includes a signal spotter 109 coupled as shown. In this example embodiment, the signal splitter 109 is not part of the RF amplifier circuit 110 and is thus shown outside the phantom lines in FIG. 2. It should be appreciated, however, that in other embodiments the RF amplifier circuit 110 may include the signal splitter 109 as a component thereof (e.g., as part of a single integrated circuit). It should also be appreciated that the functionality provided by each of the signal splitter 109, the driver circuit 112, and the RF power amplifier 118 may be shared or spot other than as illustrated in FIG. 2.

The signal splitter 109 has an input adapted to couple to a pulsed signal generator circuit 107. Signal splitter 109 receives pulsed signals from the pulse signal generator circuit 107 and in response thereto splits the pulsed signals into split signals, here first and second split signals, at first and second outputs thereof. In the embodiment shown, the signal sputter 109 is provided as a Wilkinson splitter. However, it is to be appreciated that in some embodiments signal splitter 109 can be provided as a different type of splitter capable of providing some level of isolation between the first and second outputs. Examples include, but are not limited to, Lange couplers and hybrid couplers. The pulsed signal generator circuit 107 can, for example, be controlled by a processor (not shown) coupled to or included within the RF amplifier circuit 110, but it is not so limited.

The RF amplifier circuit 110 has first and second inputs adapted to couple to the first and second outputs of signal sputter 109. The driver circuit 112, which includes first and second sub-driver circuits 114a, 114b in the illustrated embodiment, has first and second inputs coupled to the first and second inputs of the RF amplifier circuit 110. The signal splitter 109 may generate and provide substantially equal signals to first and second sub-driver circuits 114a and 114b. However, in such embodiments the difference in response characteristics of first and second sub-driver circuits 114a and 114b creates different output signals at respective output ports. For example, first sub-driver circuit 114a can be provided having a faster rise/fall time but a limited current capacity and second sub-driver circuit 114b can be provided having a slower rise/fall time and large current capacity. The first sub-driver circuit 114a has an input coupled to the first driver circuit input. The first sub-driver circuit 114a receives the first split signal and in response thereto generates a first driver signal at an output thereof. The second sub-driver circuit 114b has an input coupled to the second driver circuit input. The second sub-driver circuit 114b receives the second split signal and in response thereto generates a second driver signal.

In one embodiment, the outputs of the first sub-driver circuit 114a and the second sub-driver circuit 114b are substantially the same as those of the first sub-driver circuit 14a and the second sub-driver circuit 14b of FIG. 1. For example, the first sub-driver circuit 114a can be capable of generating driver signals having shorter pulses (and faster rise/fall times) and a lower current level (e.g., not enough to drive the RF PA 118 alone) than driver signals output by the second sub-driver circuit 114b. In other words, the first sub-driver 114a can be provided capable of outputting driver signals having edge transition times that are smaller (or shorter) than driver signals output by the second sub-driver circuit 114b such that the driver signals produced by the first sub-driver circuit 114a have sharper edges (or sharper transitions) than the driver signals output by the second sub-driver circuit 114b, but it is not so limited.

The combiner circuit 116, which is provided from a pair of diodes 117a, 117b in the illustrated embodiment, and can be the same as or similar to the combiner circuit 16 of FIG. 1, has a first input coupled to the first sub-driver circuit output and a second input coupled to the second sub-driver circuit output. Combiner circuit 116 receives the first and second driver signals and in response thereto combines the first and second driver signals to generate a combined (or composite) driver signal. In one embodiment, the combined driver signal may include a fast rise/fall time (e.g., from the first driver signal produced by the first sub-driver circuit 114a) and a high power level (e.g., from the second driver signal produced by the second sub-driver circuit 114b). In the example embodiment shown, the driver circuit 112 has an output coupled to the combiner circuit output.

The RF PA 118, which may be the same as or similar to the RF PA 18 of FIG. 1, has an input coupled to the driver circuit output. RF PA 118 receives the combined driver signal and in response thereto generates an RF output signal at an output thereof. An output 122 of the RF amplifier circuit 110 is coupled to receive the RF output signal from the RF PA output. In one embodiment, the RF PA output forms the output 122 of the RF amplifier circuit 110.

In one embodiment, the output 122 of the RF amplifier circuit 110 is coupled to a load 124 as shown. In such embodiment, the load 124, which can be the same as or similar to the load 24 of FIG. 1, has an input coupled to receive the RF output signal from the RF amplifier circuit 110.

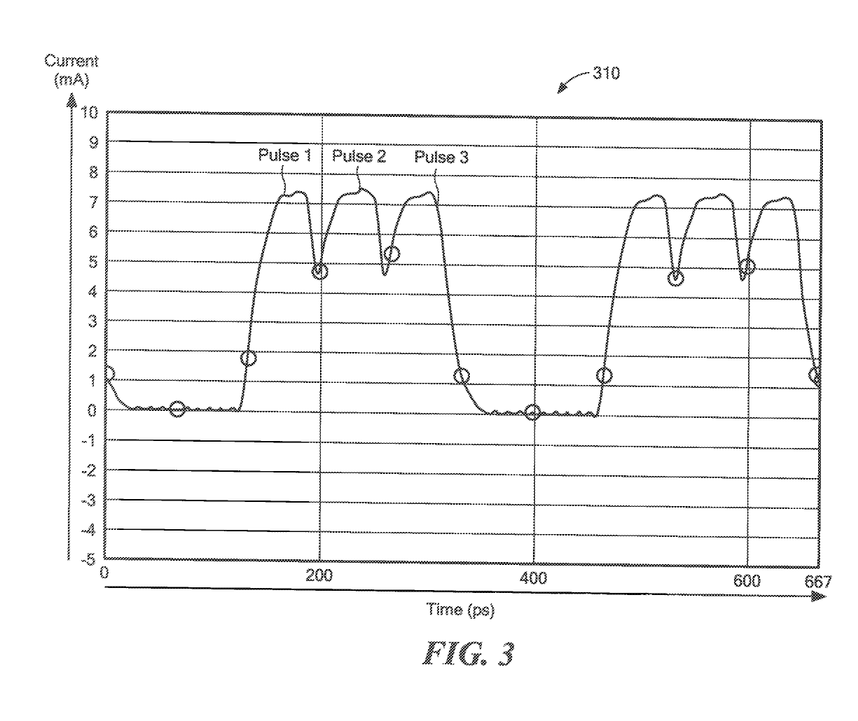

Referring now to FIG. 3, a plot 310 of current versus time has a horizontal axis with a scale in time units of picoseconds (ps) and a vertical axis with a scale in current units of milli-amperes (mA). The plot 310 shows a combined waveform generated by a combiner circuit (which can be the same as or similar to combiner circuit 116 of FIG. 2) to be received by an RF PA (which can be the same as or similar to RF PA 118 of FIG. 2). As illustrated, the combined waveform comprises a plurality of pulses (pulse 1, pulse 2, pulse 3) where the leading and trailing pulses (pulse 1, pulse 3) are representative of portions generated by a first sub-driver circuit (e.g., 114a of FIG. 2) and the middle pulse (pulse 2) is representative of portions generated by a second sub-driver circuit (e.g., 114b of FIG. 2). It should, of course, be appreciated that in other embodiments the leading and trailing pulses (pulse 1, pulse 3) may be representative of portions generated by the second sub-driver circuit (e.g., 114b of FIG. 2) and the middle pulse (pulse 2) may be representative of portions generated by the first sub-driver circuit (e.g., 114a of FIG. 2).

It is to be appreciated that the concepts, systems, circuits and techniques sought to be protected herein are not limited to use in a particular application (e.g., RF amplifier circuit). In contrast, the concepts, systems, circuits and techniques sought to be protected herein may be found useful in a wide variety of applications including amplifier circuits, in general, circuits capable of receiving a driver output signal and the like.

Having described preferred embodiments which serve to illustrate various concepts, circuits, and techniques which are the subject of this patent, it will now become apparent to those of ordinary skill in the art that other embodiments incorporating these concepts, circuits, and techniques may be used. For example, described herein is a specific example circuit topology and specific circuit implementation for achieving a desired performance. It is recognized, however, that the concepts and techniques described herein may be implemented using other circuit topologies and specific circuit implementations. Accordingly, it is submitted that that scope of the patent should not be limited to the described embodiments but rather should be limited only by the spirit and scope of the following claims.

What is claimed is:

1. A driver circuit, comprising:
a first sub-driver circuit having an input coupled to receive a first pulsed signal, the first sub-driver circuit being configured to generate a first driver signal at an output thereof in response to the first pulsed signal, the first driver signal having relatively fast edge transitions and a low current capability; and
a second sub-driver circuit having an input coupled to receive a second pulsed signal, the second sub-driver circuit being configured to generate a second driver signal at an output thereof in response to the second pulsed signal, the second driver signal having edge transitions that are slower than those of the first driver signal and a current capability that is higher than that of the first driver signal; and
a combiner to combine the first driver signal and the second driver signal to generate a combined driver signal having fast edge transitions associated with the first driver signal and higher current capability associated with the second driver signal.

2. The driver circuit of claim 1, wherein the first pulsed signal is provided from a first pulsed signal generator circuit and the second pulsed signal is provided from a second pulsed signal generator circuit.

3. The driver circuit of claim 1, wherein the first pulsed signal and the second pulsed signal are provided from a single pulsed signal generator circuit.

4. The driver circuit of claim 3, further comprising:
a splitter circuit having an input coupled to receive a pulsed input signal from the single pulsed signal generator circuit, said splitter circuit being configured to generate a first split signal at a first splitter circuit output and a second split signal at a second spatter circuit output in response to the pulsed input signal, such that the first split signal is provided as the first pulsed signal and the second split signal is provided as the second pulsed signal.

5. The driver circuit of claim 1, wherein the first pulsed signal and the second pulsed signal are substantially the same.

6. The driver circuit of claim 1, wherein the first pulsed signal and the second pulsed signal are different.

7. The driver circuit of claim 6, wherein the first pulsed signal and the second pulsed signal are substantially symmetric and substantially the same magnitude.

8. The driver circuit of claim 1, wherein the driver circuit is configured for use as a driver for a radio frequency (RF) power amplifier and the edge transitions and current capability of the combined driver signal are sufficient to provide desired operating characteristics for the RF power amplifier.

9. The driver circuit of claim 1, wherein a power amplifier is coupled to receive the combined signal.

10. An amplifier circuit comprising:
a driver circuit comprising:
a first sub-driver circuit having an input coupled to receive a first pulsed signal, the first sub-driver circuit being configured to generate a first driver signal at an output thereof in response to the first pulsed signal, the first driver signal having relatively fast edge transitions and a low current capability; and
a second sub-driver circuit having an input coupled to receive a second pulsed signal, the second sub-driver circuit being configured to generate a second driver signal at an output thereof in response to the second pulsed signal, the second driver signal having edge transitions that are slower than those of the first driver signal and a current capability that is higher than that of the first driver signal; and
a combiner to combine the first driver signal and the second driver signal to generate a combined driver signal having fast edge transitions associated with the first driver signal and higher current capability associated with the second driver signal; and
a power amplifier (PA) circuit coupled to receive the combined driver signal at an input thereof, the PA being configured to amplify the combined driver signal to generate an amplified output signal at en output thereof, wherein the edge transitions and current capability of the combined driver signal are sufficient to provide desired operating characteristics for the amplifier circuit.

11. The driver circuit of claim 10, wherein the first pulsed signal is provided from a first pulsed signal generator circuit and the second pulsed signal is provided from a second pulsed signal generator circuit.

12. The driver circuit of claim 10, wherein the first pulsed signal and the second pulsed signal are provided from a single pulsed signal generator circuit.

13. The driver circuit of claim 12, further comprising:
a splitter circuit having an input coupled to receive a pulsed input signal from the single pulsed signal generator circuit, said splitter circuit being configured to generate a first split signal at a first splitter circuit output and a second split signal at a second splitter circuit output in response to the pulsed input signal, such that the first split signal is provided as the first pulsed signal and the second split signal is provided as the second pulsed signal.

14. The driver circuit of claim 10, wherein the first pulsed signal and the second pulsed signal are substantially symmetric and substantially the some magnitude.

15. The driver circuit of claim 10, wherein the power amplifier has a relatively low input impedance characteristic.

16. A method of driving an amplifier circuit, comprising:
generating a first driver signal and a second driver signal, the first driver signal having faster edge transitions than the second driver signal and the second driver signal having greater current capability than the first driver signal;
combining the first and second driver signals to generate a combined driver signal having a high power capability and a fast rise/fall time capability; and
providing the combined driver signal to an input of the amplifier circuit for generating an amplified output signal from the combined driver signal.

17. The method of claim 16, wherein:
generating a first driver signal includes generating the first driver signal with as first sub-driver circuit in response to a first pulsed signal received from a first pulsed signal generator and generating as second driver signal includes generating the second driver signal with a second sub-driver circuit in response to a second pulsed signal received from a second pulsed signal generator.

18. The method of claim 17, wherein:
generating a first driver signal includes generating the first driver signal with a first sub-driver circuit in response to a first pulsed signal received from a first output of a splitter circuit and generating a second driver signal includes generating the second driver signal with a second sub-driver circuit in response to a second pulsed signal received from a second output of the splitter circuit.

19. The driver circuit of claim 1, further comprising:
a third sub-driver circuit having an input coupled to receive a third pulsed signal, the third sub-driver circuit being configured to generate a third driver signal at an output thereof in response to the third pulsed signal, the third driver signal having edge transitions that are substantially the same as the first driver signal but having negative pulse values, wherein the combiner is capable of combining the first driver signal and the second driver signal with the third driver signal to generate a combined driver signal having fast edge transitions associated with the first and third driver signals and higher current capability associated with the second driver signal.

20. The driver circuit of claim 1, wherein the first pulsed signal includes both positive and negative pulse values.
